(19) United States
(12) Patent Application Publication
(10) Pub. No.: US 2010/0202111 A1
(43) Pub. Date: Aug. 12, 2010

(54) Hermetic modular power supply

(76) Inventor: Chien-Kuo Liang, Chung-Ho City (TW)

Correspondence Address: Jackson Intellectual Property Group PLLC, 106 Starvale Lane, Shipman, VA, 22971, US

(21) Appl. No.: 11/976,920

(22) Filed: Oct. 29, 2007

(51) Int. Cl. H05K 7/20

(52) U.S. Cl. 361/720

(57) ABSTRACT

A hermetic modular power supply is a lumpish power supply which is completely enclosed and fixed as a heating unit formed by a circuit board and electronic elements, with a heat conductive and dissipative material. A modular base has a plural set of power plug holes, and at least one power supply can be plugged into the power plug holes, such that the power supply can be quickly and conveniently plugged into the power plug holes for use, selectively. In addition, the power supply has functions of improving heat dissipation efficiency and prolonging a lifetime of usage of the heating unit.

### BACKGROUND OF THE INVENTION

a) Field of the Invention

The present invention relates to a hermetic modular power supply, and more particularly to a hermetic modular power supply wherein a heat conductive and dissipative material is used to enclose and fix a heating unit formed by a circuit board and electronic elements into a lumpish power supply which can be plugged into power plug holes of a modular base, such that the modular power supply can be assembled and dismantled quickly and conveniently.

In the present invention, more than one power supply can be installed on the modular base, and at a same time, a utilization of the power supply is provided both with an effect of improving heat dissipation efficiency and with an effect of prolonging stability and a lifetime of usage of the heating unit.

b) Description of the Prior Art

A conventional power supply is constituted by an interior circuit board which is constructed with heating elements including transistors and capacitors, as well as an outer casing. The power supply is cooled down by rotation of a cooling fan inside the outer casing, which causes air flow to dissipate heat from the heating elements and the circuit board. However, the conventional power supply is provided with following defects under a long term of usage:
1. If the fan is damaged and stops rotating, then the heating elements will usually be damaged by that, which results in damage to the entire power supply.
2. If the power supply is installed outdoors, such as on a lamp post of an LED road lamp, then dust, water vapors, heat, air of a high pH value, temperature, and moistures created by ambient environment will invade the circuit board and the electronic elements in the power supply, allowing the heating elements to be eroded and damaged more easily.

A single power supply is connected on a single power socket. When more LED lamps are required, then a second power supply or more should be connected on another socket of another power cable to electrically connect the power supplies with the LED lamps, which is rather time consuming in assembling and dismantling, and wastes cost of installation and disassembly.

### SUMMARY OF THE INVENTION

The primary object of the present invention is to provide a hermetic modular power supply, such that at least one power supply can be selectively plugged into power plug holes of a modular base, so as to quickly select an amount of the modular power supply for installation, thereby allowing the power supply and the modular base to be quickly and conveniently assembled and dismantled.

Another object of the present invention is to provide a hermetic modular power supply, wherein a heat conductive and dissipative material is used to enclose and adhere heating units, such as a circuit board and electronic elements, into one body, such that the heating units can be completely sealed and totally isolated from ambient environment, thereby achieving a function of moisture-proofing and preventing from water penetrating, to prolong lifetimes of usage to the circuit board and the heating elements.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a perspective view of a modular power supply of the present invention, after being assembled.

FIG. 2 shows a cross sectional view of a modular power supply of the present invention.

FIG. 3 shows an exploded view of parts of another embodiment of a modular power supply of the present invention.

FIG. 4 shows a perspective view of parts of another embodiment of a modular power supply of the present invention, after being assembled.

FIG. 5 shows a cross sectional view of parts of another embodiment of a modular power supply of the present invention.

FIG. 6 shows an exploded view of a modular power supply of the present invention, with an electric conducting terminal being an electric conducting wire.

FIG. 7 shows a perspective view of a modular power supply of the present invention, which is plugged on a modular base.

FIG. 8 shows a perspective view of still another embodiment of a modular power supply of the present invention.

FIG. 9 shows a perspective view of four modular power supplies of the present invention, after being plugged on a modular base.

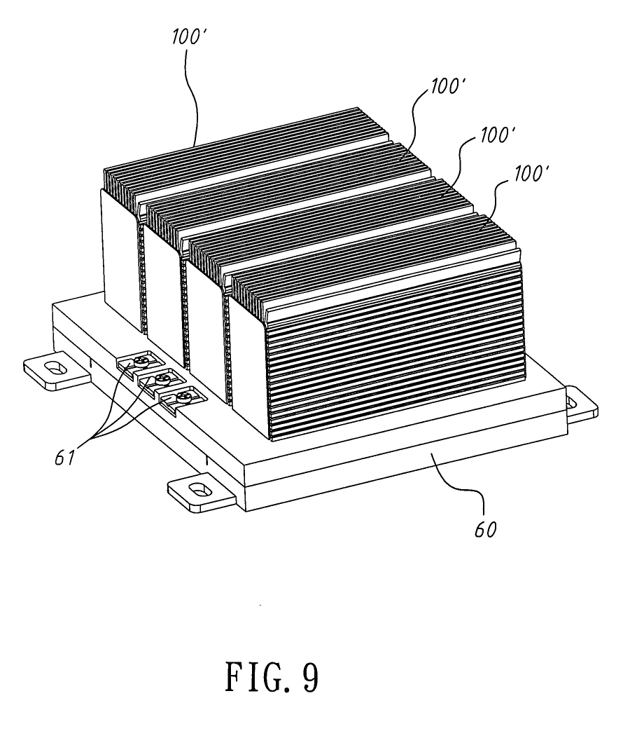

FIG. 10 shows an exploded view of parts of a modular base of the present invention.

FIG. 11 shows a flow diagram of a modular base of the present invention, which operates on an LED lamp set.

### DETAILED DESCRIPTION OF THE PREFERRED EMBODIMENTS

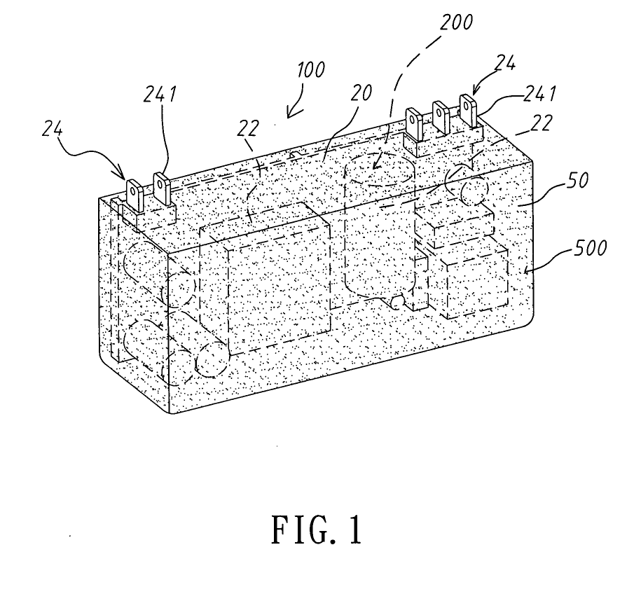

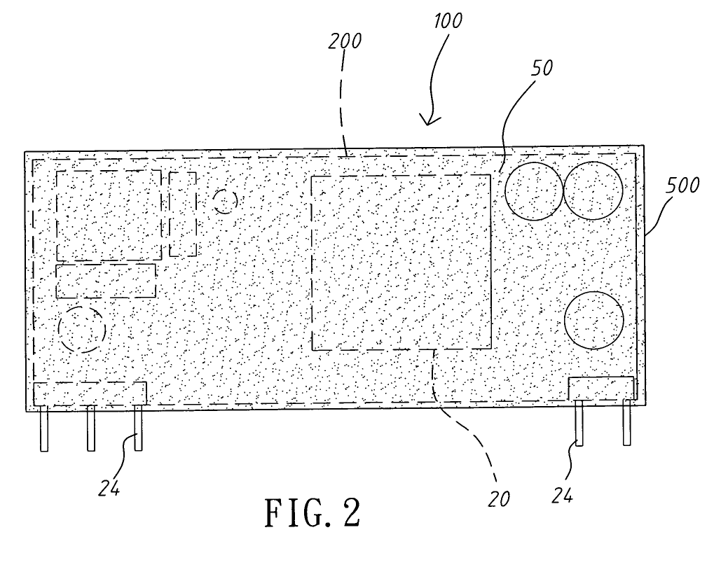

Referring to FIG. 1 and FIG. 2, the present invention is to provide a hermetic modular power supply including a circuit board 20, which is provided with heating elements 22, for serving as a heating unit 200 on which is provided with metallic electric conducting terminals 24; and a heat conductive and dissipative material 50, which serves as a unit of insulation, heat conduction and dissipation, and completely adheres the heating unit 200 into a modular power supply 100.

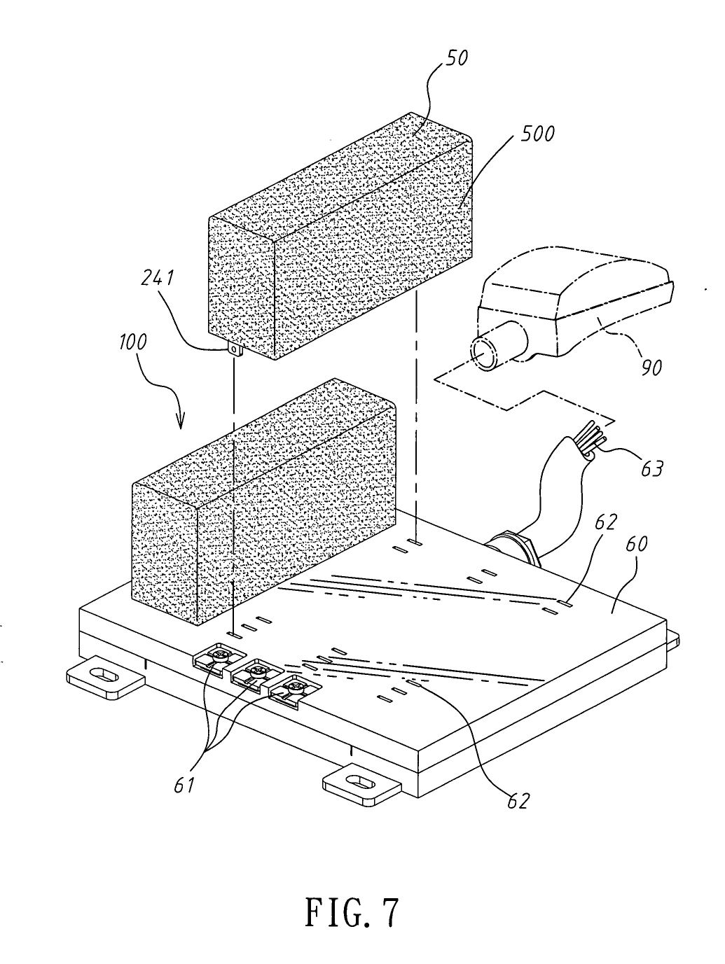

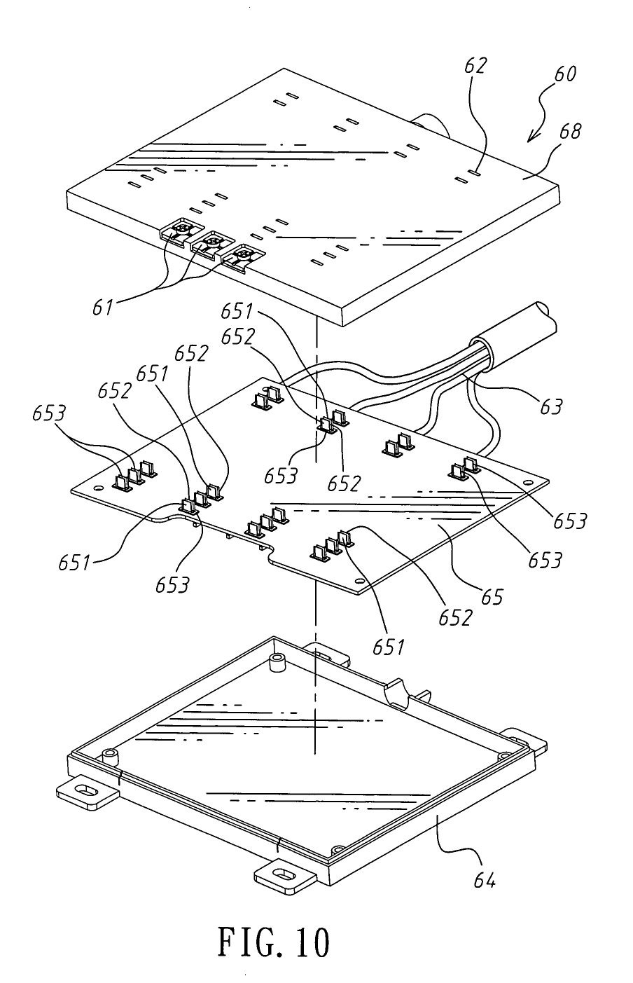

Referring to FIG. 7 and FIG. 10, a surface of a modular base 60 is provided with at least one set of AC and DC power plug holes 62. Selectively, for at least one modular power supply 100, its metallic electric conducting terminals 24 are plugged into the power plug holes 62.

Referring to FIG. 10, the modular base 60 is composed of:
(a) A bottom seat 64, an interior of which is fixed with a circuit board 65, with the circuit board 65 being welded with a plurality of electric conducting spring leaves 651, 652, and a gap between each two neighboring electric spring leaves 651, 652 forming a slot 653; and
(b) An upper cover 68, a surface of which is provided with at least one set of power plug holes 62, with a lower side of each plug hole 62 corresponding to the slot 653, and the upper cover 68 being assembled on the bottom seat 64. Referring to FIG. 1 and FIG. 2, the heat conductive and dissipative material 50 is a lumpish body 500 formed by an insulating heat conductive paste and glue, which is provided with functions of heat conduction and dissipation, adherence, and isolation, so as to isolate the heating unit 200 from ambient environment.

Referring to FIG. 1 and FIG. 2, each metallic electric conducting terminal 24 is protruded out of the lumpish body 500, and can be selectively an electric conducting plate 241.

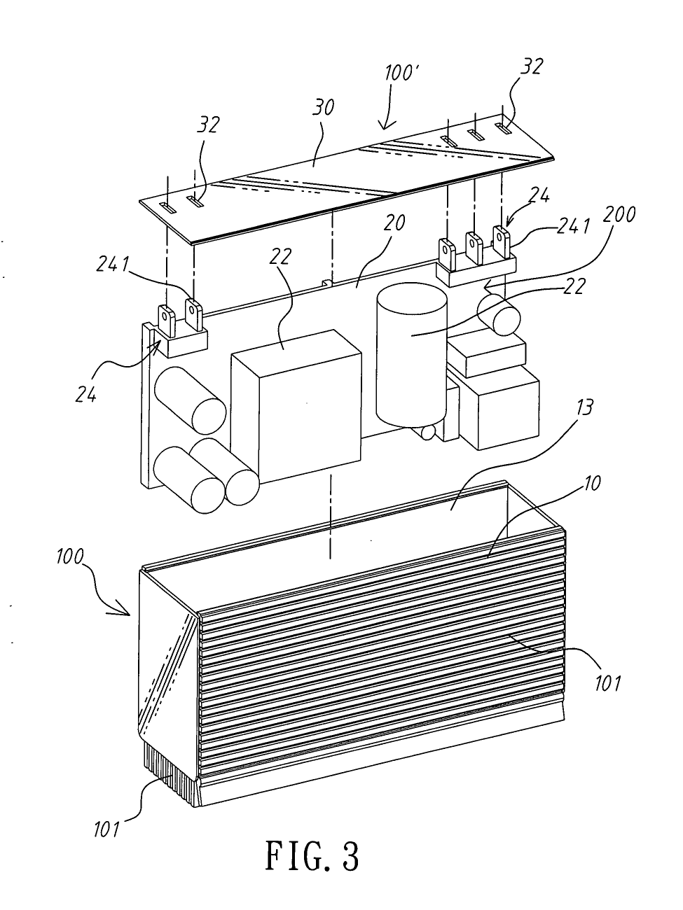

Referring to FIGS. 3 to 5, the present invention is to provide a hermetic modular power supply including a circuit board 20, which is provided with heating elements 22, for serving as a heating unit 200 on which is provided with metallic electric conducting terminals 24; a heat conductive and dissipative material 50, which serves as a unit of insulation, heat conduction and dissipation, and completely adheres the heating unit 200 into a modular power supply 100; a heat dissipating shade 10 into which is provided with a container 13; and a lumpish body 500, which is tightly fitted into the container 13 to form a modular power supply 100′, and forms a heat conduction medium to conduct heat generated by the heating unit 200 to the heat dissipating shade 10 for dissipating heat outward.

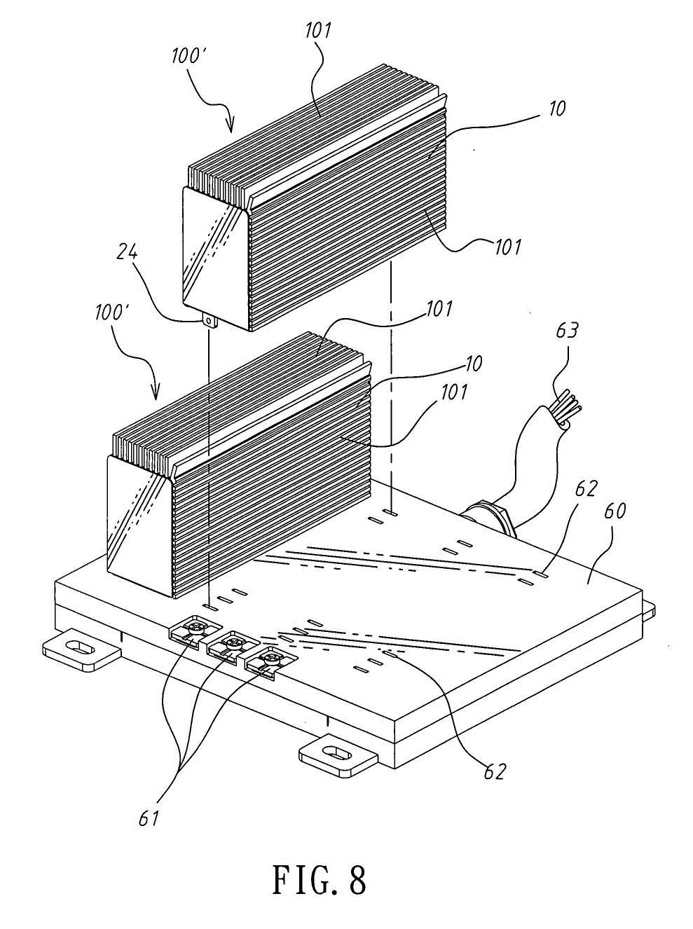

Referring to FIG. 8 and FIG. 10, a surface of a modular base 60 is provided with at least one set of power plug holes 62, and the metallic electric conducting terminals 24 of more than one modular power supply 100′, selectively, are plugged into the power plug holes 62.

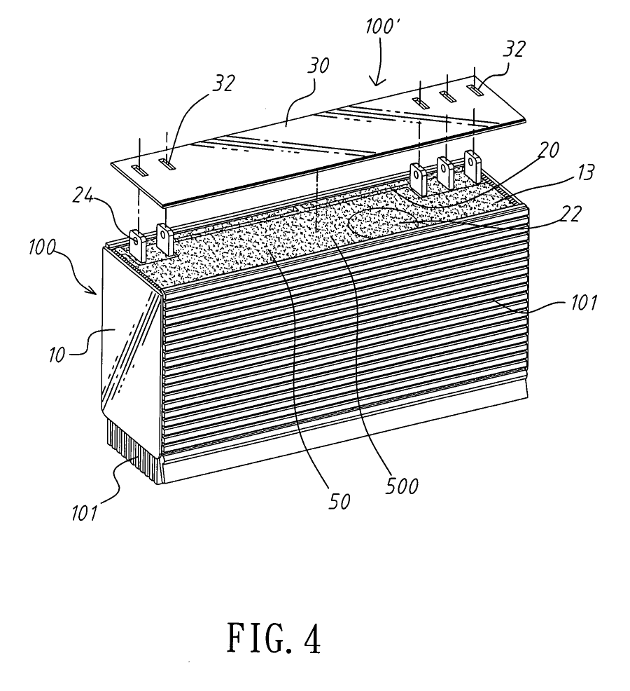

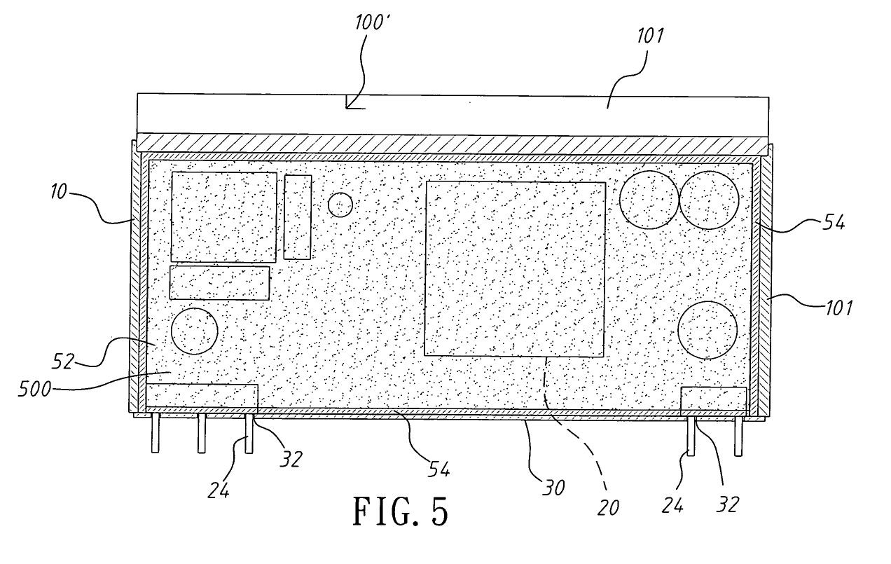

Referring to FIG. 4 and FIG. 5, the heat conductive and dissipative material 50 is composed of an inner layer which is formed by a heat conductive paste 52, and an outer layer, which is formed by a layer of heat conductive glue 54, and encloses the inner layer.

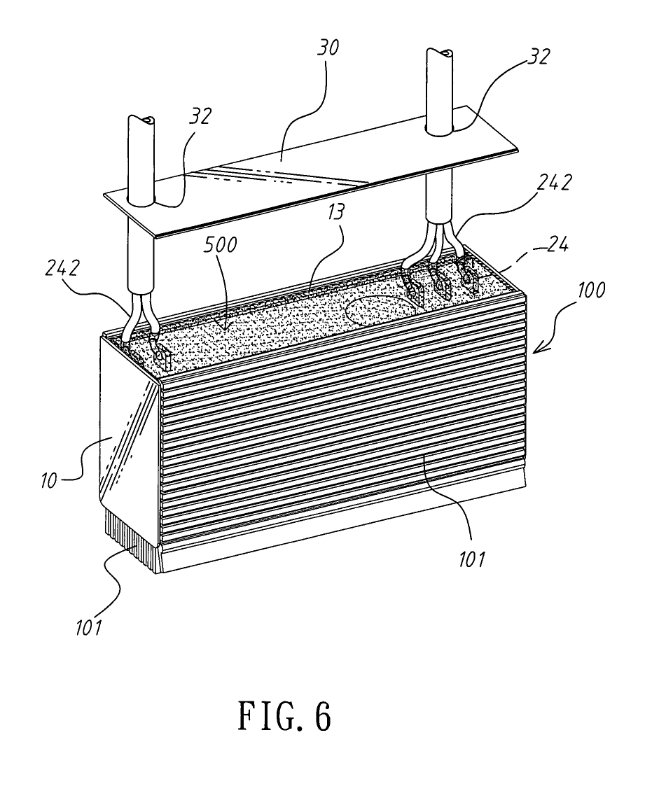

Referring to FIG. 6, the metallic electric conducting terminal 24 can be selectively designed as an electric conducting wire 242 which is protruded out of the lumpish body 500. An insulating cover board 30 is used to seal the container 13, and the electric conducting wire 242 is transfixed out of a through-hole 32 of the cover board 30.

Referring to FIG. 4 and FIG. 5, the metallic electric conducting terminal 24 can be designed as a plate, which is protruded out of the lumpish body 500.

Referring to FIG. 7, the hermetic modular power supplies 100, 100′ can be used for an outdoor LED lamp set 90.

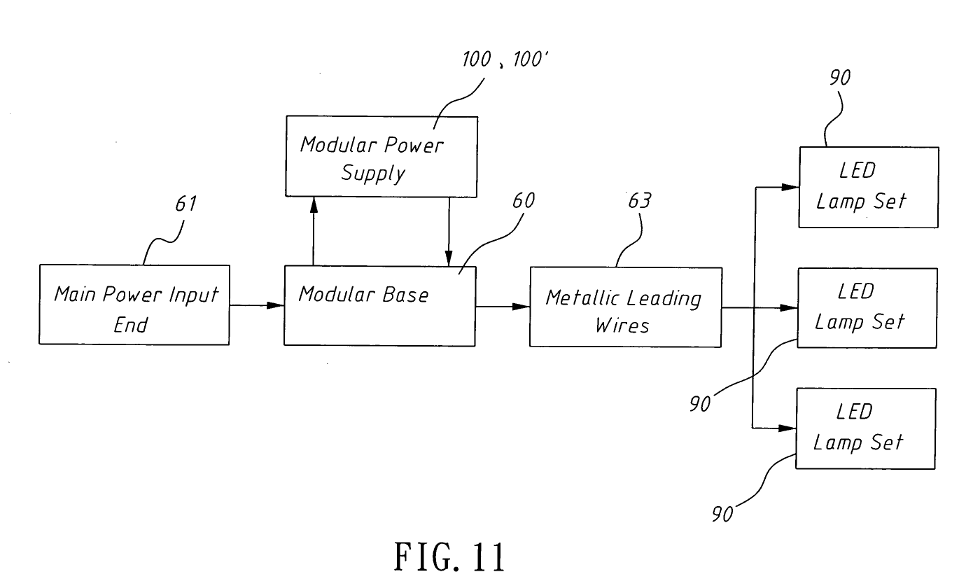

As shown in FIG. 7 and FIG. 11, a side of the modular base 60 is provided with AC main power input ends 61, whereas the other side is provided with metallic leading wires 63 for outputting a second power. The power supply 100, which is plugged into the power plug holes 62, processes the AC main power into proper values of DC voltage and current, defined as the second power and outputted from the metallic leading wires 63. The metallic leading wires 63 are connected to the LED lamp set 90, allowing the LED lamp set 90 to acquire proper values of working voltage and current for illuminating and lighting.

Referring to FIG. 7, there are four sets of power plug holes 62, with each set being divided into the AC power plug holes 62 and the DC power plug holes 62, being one embodiment of the present invention. The plug holes 62 can be added or decreased, according to an actual number of LED illuminating chips in the LED lamp set 90, and a number of the power supplies 100 can be configured dependent upon the number of LED illuminating chips in the LED lamp set 90. In other words, if the LED illuminating chips in the LED lamp set 90 are plenty, then more power supplies 100 should be plugged on the modular base 60. As shown in FIG. 7, the modular base 60 can provide for plugging with four power supplies 100.

Accordingly, when the LED illuminating chip is temporarily added to the lamp set 90 in environment of the embodiment, the second power can be provided to the newly added LED lamp set 90 by only plugging a newly added power supply 100 into the reserved plug holes 62. In addition, when the LED illuminating chip is temporarily decreased from the LED lamp set 90 in the environment of the embodiment, power can saved by just pulling one power supply 100 out of the plug holes 62 on the modular base 60.

If one of the power supplies 100 is damaged and cannot operate, then only a new power supply 100 is plugged into the plug holes 62 to accomplish the replacement.

Therefore, by the design of the modular power supply 100, one or more than one power supply can be flexibly selected for being plugged on or dismantled from the modular base 60, such that the power supply 100 and the modular base 60 can be assembled and dismantled quickly and conveniently.

Referring to FIG. 3, the circuit board 20 of the present invention is welded with the heating elements 22 which can be constituted by chips, capacitors, and resistors. If the electric conducting plate 241 is chosen for the metallic electric conducting terminal 24, then the electric conducting plate 241 can be plugged into the power plug hole 62 on the modular base 60 (as shown in FIG. 7). The heating elements 22 will release temperature, enabling the entire circuit board 20 to form into a heating unit 200. As the heat conductive and dissipative material 50 completely seals and encloses the entire circuit board 20, as shown in FIG. 1 and FIG. 2, the temperature generated by the circuit board 20 and the heating elements 22 will be immediately dissipated everywhere by air through the heat conductive and dissipative material 50, from the lumpish body 500 formed by the heat conductive and dissipative material 50. As shown in FIG. 3 and FIG. 4, the heat dissipating shade 10 is made by an aluminum alloy or other heat dissipating metals, and surfaces of the heat dissipating shade 10 are provided with cooling fins 101 which can directly dissipate the temperature into the air, thereby improving a heat dissipating effect of the power supply 100′ to increase a lifetime of usage of the power supply 100′.

Referring to FIG. 3 and FIG. 4, the heat dissipating shade 10, the insulating cover board 30, and the circuit board 20 are adhered and fixed into one body by the heat conductive and dissipative material 50. As shown in FIG. 8, the power supply 100′ which is provided with the heat dissipating shade 10 can be modularized into one or more than one set, and a proper number can be selected for use by plugging the metallic electric conducting terminals 24 into the power plug holes 62 on the base 60. As shown in FIG. 7, the lumpish body 500 formed by the heat conductive and dissipative material 50 can be used by plugging the electric conducting plates 241 into the power plug holes 62 on the base 60. As shown in FIG. 1, as the insulating heat conductive and dissipative material 50 adheres and encloses the circuit board 20 and the heating elements 22, the circuit board 20 and the heating elements 22 can be prevented from being contact with ambient air, thereby improving stabilities and lifetimes of usage of the circuit board 20 and the heating elements 22.

Referring to FIG. 5, the insulating heat conductive and dissipative material 50 of the present invention is not limited to a heat conductive medium of a single material. A solid heat conductive paste 52 can be also selected as a material to enclose the circuit board 20 and the heating elements 22 (as shown in FIG. 5), with an outer layer being enclosed with a layer of heat conductive glue 54. As the heat conductive glue 54 is provided with viscosity and can prevent from water penetrating, the heat dissipating shade 10, the insulating cover board 30, and the heat conductive paste 52 can be connected as one body, which is also an effective embodiment of the present invention.

Referring to FIG. 6, the metallic electric conducting terminal 24 of the present invention is not limited to an implementation of the metallic electric conducting plate, and the metallic electric conducting terminal 24 can be also connected to electric conducting wires 242, selectively. Outer plugs of the electric conducting wires 242 (not shown in the drawing) can be plugged respectively onto the AC and DC power.

Referring to FIG. 1 and FIG. 2, as the heating unit, such as the circuit board 20, of the present invention is connected and enclosed into one body by the heat conductive and dissipative material 50, the circuit board 20 and the heating elements 22 that are welded on it are all isolated from ambient environment. Therefore, rain, moistures, gas or fluid of a high pH value, little bugs, and other materials in the ambient environment will not penetrate into the circuit board 20, the heating elements 22, and the heat conductive and dissipative material 50, so as to achieve objects of water-proofing, moisture-proofing, and material penetration-proofing, such that the power supplies 100, 100′ of the present invention can be used in all kinds of conditions; for example, the power supplies can be installed on a lamp post or a neighboring area of an outdoor LED lamp set 90 to provide power to the LED lamp set 90 (as shown in FIG. 11).

For the hermetic power supply 100, 100′, the heating elements 22 and the circuit board 20 are completely enclosed and sealed, and hence the stability and lifetime of usage can be improved. The power supply 100, 100′ is formed as one body by the heat conductive and dissipative material 50, and therefore, is completely isolated from the ambient environment, so as to prevent from moisture, water penetrating, penetration of gas or fluid of a high pH value, and little bugs, thereby improving the lifetimes of usage of the circuit board and the heating elements. In addition, the implementation of the power supply 100, 100′ is not affected by the ambient environment, to manifest effects of high efficiency and stability.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A hermetic modular power supply comprising a circuit board, which is provided with heating elements, for serving as a heating unit on which is provided with metallic electric, conducting terminals; a heat conductive and dissipative material, which serves as a unit of insulation, heat conduction and dissipation, and completely adheres the heating unit into a modular power supply; and a modular base on which is provided with at least one set of AC power plug holes and one set of DC power plug holes; for at least one modular power supply, selectively, the metallic electric conducting terminals being plugged into at least one set of the power plug holes.

2. The hermetic modular power supply according to claim 1, wherein the modular base includes:
(a) a bottom seat, an interior of which is fixed with a circuit board, with the circuit board being welded with a plurality of electric conducting spring leaves, and a slot being formed by a gap between each two neighboring electric conducting spring leaves;
(b) an upper cover, a surface of which is provided with at least one set of power plug holes, with a lower side of each plug hole corresponding to the slot, and the upper cover being assembled on the bottom seat.

3. The hermetic modular power supply according to claim 1, wherein the heat conductive and dissipative material is a lumpish body constituted by an insulating heat conductive glue and paste, being provided with functions of heat conduction and dissipation, adhering, and isolation, so as to isolate the heating unit from ambient environment.

4. The hermetic modular power supply according to claim 1, wherein the metallic electric conducting terminal is protruded out of the lumpish body, and is selectively an electric conducting plate.

5. The hermetic modular power supply according to claim 1, wherein the hermetic power supply is used for an outdoor LED lamp set.

6. A hermetic modular power supply comprising a circuit board, which is provided with heating elements, for serving as a heating unit on which is provided with metallic electric conducting terminals; a heat conductive and dissipative material, which serves as a unit of insulation, heat conduction and dissipation, and completely adheres the heating unit into a modular power supply; a heat dissipating shade into which is provided with a container; a lumpish body which is tightly put into the container to form a modular power supply, with the lumpish body forming a heat conduction medium to conduct heat generated by the heating unit to the heat dissipating shade for dissipating heat outward; and a modular base on which is provided with at least one set of power plug holes; for at least one modular power supply, selectively, the metallic electric conducting terminals being plugged into the power plug holes.

7. The hermetic modular power supply according to claim 6, wherein the heat conductive and dissipative material includes a heat conductive paste as an inner layer, with an outer layer of the heat conductive paste being enclosed with a layer of heat conductive glue.

8. The hermetic modular power supply according to claim 6, wherein the metallic electric conducting terminal is selectively designed as an electric conducting wire which is protruded out of the lumpish body, the container is sealed by an insulating cover board, and the electric conducting wire is penetrated out of a through-hole of the cover board.

9. The hermetic modular power supply according to claim 6, wherein the metallic electric conducting terminal is designed as a plate which is protruded out of the lumpish body.

10. The hermetic modular power supply according to claim 6, wherein the hermetic modular power supply is used for an outdoor LED lamp set.
